(19) United States
(12) Patent Application Publication
(10) Pub. No.: US 2008/0035948 A1
(43) Pub. Date: Feb. 14, 2008

(54) Light emitting diode package

(75) Inventors: Sang Hyun Shin, Gyunggi-Do (KR); Seog Moon Choi, Seoul (KR); Young Ki Lee, Seoul (KR); Yong Sik Kim, Gyunggi-Do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/714,156

(22) Filed: Mar. 6, 2007

(30) Foreign Application Priority Data
Mar. 9, 2006 (KR) 10-2006-0022141

(51) Int. Cl. H01L 33/00

(52) U.S. Cl. 257/99; 257/E33.058

(57) ABSTRACT

A light emitting diode package for preventing an electric short circuit among semiconductor layers and with excellent bonding strength. The light emitting diode package includes a package substrate, a light emitting diode chip bonded to an upper surface of the package substrate, and a bonding material for bonding the light emitting diode chip to the package substrate. The package substrate has a recess formed in a bonding surface thereof to accommodate the bonding material.

### CLAIM OF PRIORITY

This application claims the benefit of Korean Patent Application No. 2006-0022141 filed on Mar. 9, 2006, in the Korean Intellectual Property Office, the disclosure of which is incorporated herein by reference.

### BACKGROUND OF THE INVENTION

1. Field of the Invention

The present invention relates to a light emitting diode (hereinafter, referred to as ‘LED’) package and, more particularly, to an LED package which prevents a short circuit among semiconductor layers due to a chip bonding material and has excellent bonding strength between an LED chip and a substrate.

2. Description of the Related Art

In general, a semiconductor LED has gained attention in various applications as an environmentally friendly light source that does not cause any pollution. Recently, an LED device emitting monochromatic light is combined with phosphor to provide a different wavelength of light. Such an LED product is manufactured by bonding an LED chip having various structures to a package substrate.

FIG. 1 is a sectional view illustrating a conventional LED package with a vertical-structure LED chip mounted therein. Referring to FIG. 1, the LED package 10 includes a package substrate 11 and a vertical-structure LED chip 12 mounted on the package substrate 11. The LED chip 12 includes semiconductor layers 12c sequentially stacked on a chip substrate 12a (e.g. a SiC substrate) and a chip electrode 12b. The package substrate 11 has substrate electrodes 11a and 11b formed on an upper surface thereof. The semiconductor layers 12c includes an n-type semiconductor layer, an active layer and a p-type semiconductor layer, and receives power through the chip substrate 12a and the chip electrode 12b to emit light at the active layer. The chip substrate 12a is electrically connected to the substrate electrode 11a through a wire (wire bonding), and the chip electrode 12b is bonded (chip bonding) to the substrate electrode 11b through a conductive bonding material 13 such as Pb-Sn.

Typically, in order for chip bonding, heat and pressure is applied to bond the LED chip 12 to the substrate 11. At this time, due to the pressure, the bonding material 13 protrudes laterally and may cause an electric short circuit among the semiconductor layers 12c (the n-type semiconductor layer, the active layer and the p-type semiconductor layer) in the LED chip 12. Such an electric short circuit among the semiconductor layers is a fatal problem, which may cause the LED chip to lose its function. In addition, in order to attain higher product reliability, the bonding strength between the LED chip 12 and the package substrate 11 should be further enhanced.

To prevent such an electric short circuit, there has been suggested a method in which a flux is formed on a bonding surface of the package electrode 11b so that the LED chip 12 can be bonded to the package substrate 11 by heat without applying pressure. However, such a flux not only can corrode the substrate but also may increase heat resistance of the LED package, deteriorating the heat radiation characteristics.

Also in the LED package using a vertical-structure LED chip, there has been a problem of weak bonding strength between the LED chip and the package substrate, which needs to be improved.

### SUMMARY OF THE INVENTION

The present invention has been made to solve the foregoing problems of the prior art and therefore an aspect of the present invention is to provide an LED package which can prevent an electric short circuit among semiconductor layers due to a bonding material for bonding an LED chip.

Another aspect of the invention is to provide an LED package which can increase the bonding strength between an LED chip and a package substrate.

According to an aspect of the invention, the invention provides a light emitting diode package which includes: a package substrate; a light emitting diode chip bonded to an upper surface of the package substrate; and a bonding material for bonding the light emitting diode chip to the package substrate, wherein the package substrate has a recess formed in a bonding surface thereof for accommodating the bonding material.

According to an embodiment of the present invention, the LED chip may be a vertical-structure LED chip having a chip electrode bonded to the package substrate.

If the LED chip is a vertical-structure LED chip having a chip electrode bonded to the package substrate, the bonding material may be a eutectic alloy. In this case, the package substrate has a package electrode formed on an upper surface thereof, and the chip electrode and the package electrode can be eutectic bonded.

If the chip electrode is eutectic bonded to the package electrode, the chip electrode may be made of a material selected from the group consisting of Au-Sn, Au-Ni, Au-Ge, Au-Si, Au, Sn and Ni. In addition, the package electrode may be made of a material selected from the group consisting of Au-Sn, Au-Ni, Au-Ge, Au-Si, Au, Sn and Ni. For example, the chip electrode may be an Au-Sn layer and the package electrode may be an Au layer. Conversely, the chip electrode may be an Au layer and the package electrode may be an Au-Sn layer.

According to the present invention, the bonding material may be of various materials besides the eutectic alloy (from eutectic bonding). For example, the bonding material may be a cream solder of Pb-Sn, etc.

The package substrate can be made of one selected from the group consisting of a metal, ceramics, FR4, polyimide, Si and BT resin. The LED package can further include a plating layer formed between the package substrate and the package electrode. In this case, the plating layer may be made of one selected from the group consisting of Au, Ni, Pt, Al and Ag.

According to another embodiment of the present invention, the LED chip may be a horizontal-structure LED chip having an insulation substrate such as a sapphire substrate. In this case, the insulation substrate is bonded to the bonding surface of the package substrate, and the bonding material may include an epoxy resin. The epoxy resin may be an Ag epoxy resin, in particular.

Preferably, the recess is formed in a net shape. It is preferable that the bonding material completely covers the recess. The recess can have various sectional shapes such as one selected from the group consisting of a rectangle, a triangle and a semicircle.

According to the present invention, the recess is formed in the bonding surface of the chip-bonded package substrate. This recess accommodates the bonding material and provides a passage for the bonding material, thereby preventing an electric short circuit due to an extra amount of the bonding material. In addition, the recess functions to increase the strength between the chip-bonded LED chip and the package substrate. In order to prevent the electric short circuit and increase the bonding strength, the recess is preferably formed in a net shape.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view illustrating a conventional LED package;

FIG. 2 is a sectional view illustrating an LED package according to an embodiment of the present invention;

FIG. 3 is a sectional view illustrating an LED package according to another embodiment of the present invention; and

FIG. 4 is a plan view illustrating a recess formed in a package substrate of the LED package according to an embodiment of the present invention.

### DETAILED DESCRIPTION OF THE PREFERRED EMBODIMENT

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity and the same reference numerals are used throughout to designate the same or similar components.

FIG. 2 is a sectional view illustrating an LED package according to an embodiment of the present invention. Referring to FIG. 2, the LED package 100 includes an LED chip 120 and a package substrate 110 on which the LED chip 120 is mounted. The LED chip 120 is a vertical-structure LED chip including a chip substrate 121 made of a conductive material such as SiC. On the chip substrate 121, semiconductor layers 123 are formed. The semiconductor layers 123 include a first conductivity type semiconductor layer 123a, an active layer 123b and a second conductivity type semiconductor layer 123c. Here, the first conductivity and second conductivity types may be an n-type and a p-type, respectively. Conversely, the first conductivity and the second conductivity types can be a p-type and an n-type, respectively. In addition, the LED chip 120 includes a chip electrode 122 bonded to a bonding surface of the package substrate 110. The semiconductor layers 123 receive current by a voltage applied from the chip substrate 121 and the chip electrode 122, thereby emitting light at the active layer 123b.

The package substrate 110 has a substrate electrode 111 formed on an upper surface thereof. A plating layer 112 can be formed between the package substrate 110 and the substrate electrode 111. The plating layer 112 can be made of a material selected from the group consisting of, for example, Au, Ni, Pt, Al and Ag. The substrate electrode 111 is bonded to the chip electrode 122 to supply a voltage to the chip electrode 122. The package electrode 111 and the chip electrode 122 are bonded by a conductive bonding material 130.

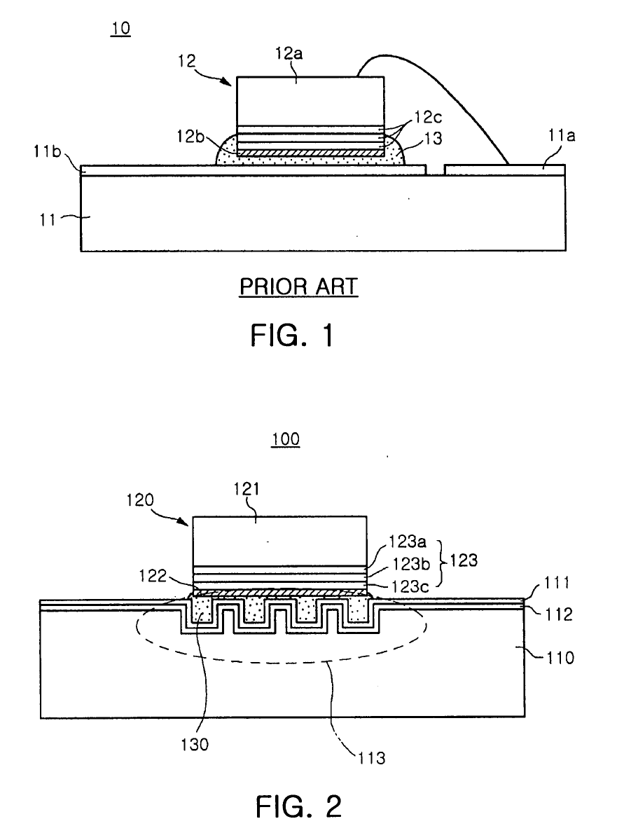

As shown in FIG. 2, the package substrate 110 has a recess 113 formed in a bonding surface thereof to accommodate an extra amount of the conductive bonding material 130. With a planar bonding surface as in the prior art (see FIG. 1), the extra amount of the conductive bonding material 130 may be squeezed out of the interfacial bonding surface by the pressure applied during chip bonding. However, the recess 113 accommodates the extra amount of the conductive bonding material 130 and thereby prevents the bonding material 130 from being squeezed out of the bonding surface. Thereby, the conventionally problematic electric short circuit among the semiconductor layers 123 can be effectively prevented.

In addition, the recess 113 defines indentations in the bonding surface, increasing the substantial bonding area and increasing the bonding strength between the package substrate 110 and the LED chip 120. The effects of increased bonding strength during the chip bonding can be applied to not only the case of bonding a vertical-structure LED chip but also to the case of bonding a horizontal-structure LED chip (described later).

The surface of the recess 113 can have various shapes in a plan view. In particular, it is preferable that the recess 113 is formed in a net shape. An example of such a net-shaped recess 113 is illustrated in FIG. 4. Referring to FIG. 4, the package substrate 110 has a net-shaped recess 113 formed in the bonding surface thereof. Such a net-shaped recess 113 provides a passage for the bonding material 130, thereby effectively accommodating the extra amount of the conductive bonding material 130 during the chip bonding.

The recess 113 can have various cross-sectional shapes. FIG. 2 exemplifies a recess 113 having a roughly rectangular section, but the present invention is not limited thereto. For example, the recess 113 may have a triangular or a semicircular section. The recess 113 can be formed by a chemical etching, punching or stamping process performed on the package substrate 110.

As shown in FIG. 2, it is preferable that the conductive bonding material 130 completely covers the recess 113 for bonding. This is because if an empty space (or air bubble) is formed between the package electrode 111 and the conductive bonding material 130, the bonding strength may be weakened or the heat radiation characteristics may be degraded. Therefore, it is preferable that the depth of the recess 113 is suitably adjusted according to the thickness of the conductive bonding material 130.

According to an embodiment of the present invention, the package substrate 110 and the LED chip 120 can be eutectic bonded. In this case, the conductive bonding material 130 can be a eutectic alloy from the eutectic bonding. The eutectic bonding between the package substrate 110 and the LED chip 120 occurs between the package electrode 111 and the chip electrode 122, which are made of a metal that can be eutectic bonded.

In order for eutectic bonding between the package electrode 111 and the chip electrode 122, the chip electrode 122 may be made of a material selected from the group consisting of Au-Sn, Au-Ni, Au-Ge, Au-Si, Au, Sn and Ni. In addition, the substrate electrode 111 can also be made of a material selected from the group consisting of Au-Sn, Au-Ni, Au-Ge, Au-Si, Au, Sn and Ni.

In an exemplary embodiment, the chip electrode 122 can be made of Au-Sn and the substrate electrode 111 can be made of Au. For example, the chip electrode 122 can be made of Au-Sn with a weight ratio of 8:2 of Au:Sn, and the substrate electrode 111 can be made of Au. When heat and pressure is applied as the Au-Sn chip electrode 122 is placed in contact with the Au substrate electrode 111, the contacting parts of the electrodes 122 and 111 are melted, and thus Au-Sn eutectic mixture (eutectic alloy) is made from the interface of the electrodes 122 and 111. This eutectic alloy has a predetermined composition ratio of Au:Sn and functions as the conductive bonding material 130. The conductive bonding material 130 made of the eutectic alloy allows the LED chip 120 to be more strongly attached to the substrate electrode 111. The eutectic bonding not only can realize high bonding strength but also has an advantage of not requiring a separate bonding material applied additionally. As an alternative embodiment, the chip electrode 122 can be made of Au and the substrate electrode 111 can be made of Au-Sn.

The LED chip 120 can be bonded to the package substrate 110 by various bonding materials besides the eutectic alloy (generated from the eutectic bonding). For example, the LED chip 120 can be bonded to the package substrate 110 using a separate bonding material 130 made of a cream solder such as Pb-Sn. Such a cream solder can be applied on the chip electrode 122 or the package electrode 111 in advance before chip bonding.

The package substrate 110 not only functions as a submount for mounting the LED chip 120 but also as a heat sink for radiating the heat generated from the LED chip 120 to the outside. Therefore, it is preferable that the package substrate 110 is made of a highly heat conductive metal such as Al(aluminum) or Cu(copper), ceramics or Si. In addition, the package substrate 110 can be made of generally used FR4, polyimide or BT resin. In order to easily radiate the heat generated form the LED chip 120 to the outside, it is preferable that the recess 113 is completely covered by the bonding material 130 because an empty space or an air bubble formed in the recess 113 may hinder heat radiation.

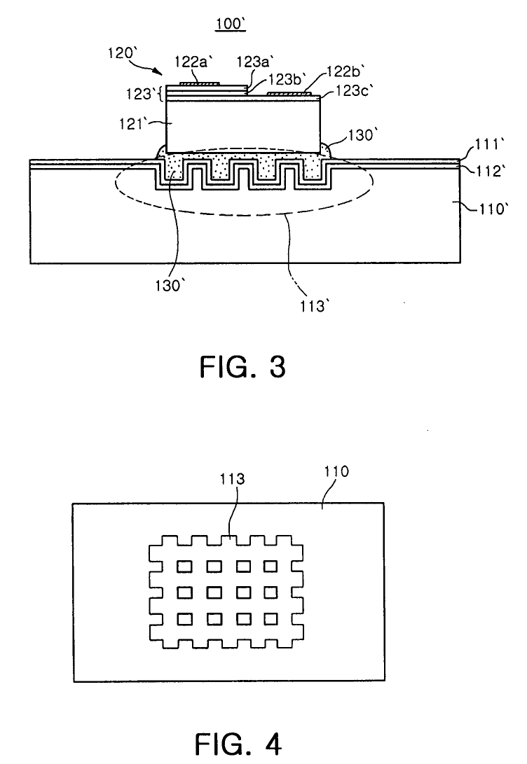

FIG. 3 is a sectional view illustrating an LED package according to another embodiment of the present invention. In the embodiment shown in FIG. 3, the LED chip 120′ is a horizontal-structure LED chip in which the p-electrode 122a′ and the n-electrode 122b′ are disposed on the same side. The LED chip 120′ includes a chip substrate 121′ made of an insulation material such as sapphire and semiconductor layers 123′ formed on the chip substrate 121′. The semiconductor layers 123′ includes a first conductivity type (e.g. a p-type) semiconductor layer 123a′, an active layer 123b′ and a second conductivity type (e.g. an n-type) semiconductor layer 123c′

A plating layer 112′ and a package electrode 111′ are formed on an upper surface of a package substrate 110′. The package substrate 110′, the plating layer 112′ and the substrate electrode 111′ can be made of the same materials as described in the aforedescribed embodiment (see FIG. 2). The chip substrate 121′ of the LED chip 120′ is bonded to a bonding surface of the package substrate 110′ by a bonding material 130′. It is preferable that the bonding material 130′ is made of an Ag epoxy resin having excellent heat conductivity, but the present invention is not limited thereto.

As shown in FIG. 3, a recess 113′ for accommodating the bonding material 130′ is formed in the bonding surface of the package substrate 110′ in this embodiment as well. This recess 113′ increases the bonding area and thereby increases the bonding strength between the LED chip 120′ and the package substrate 110′. That is, not only the side surface and the undersurface of the recess 113′ can be utilized as the bonding area, but also the recess 113′ defines indentations in the bonding surface, thereby resulting in higher bonding strength than in the prior art. In particular, as shown in FIG. 4, in a case where the recess 113′ has a net shape on the bonding surface in a plan view, the bonding strength is further enhanced.

According to the present invention as set forth above, a recess is formed in a bonding surface of the package substrate to accommodate an extra amount of a bonding material, thereby effectively preventing an electric short circuit among semiconductor layers due to the bonding material. Furthermore, the recess defines indentations in the bonding surface, increasing the bonding strength between an LED chip and a package substrate. This in turn allows an LED package with high reliability.

While the present invention has been shown and described in connection with the exemplary embodiments, it will be apparent to those skilled in the art that modifications and variations can be made without departing from the spirit and scope of the invention as defined by the appended claims.

What is claimed is:

1. A light emitting diode package comprising:
a package substrate;
a light emitting diode chip bonded to an upper surface of the package substrate; and
a bonding material for bonding the light emitting diode chip to the package substrate,
wherein the package substrate has a recess formed in a bonding surface thereof for accommodating the bonding material.

2. The light emitting diode package according to claim 1, wherein the LED chip comprises a vertical-structure LED chip having a chip electrode bonded to the package substrate.

3. The light emitting diode package according to claim 2, wherein the bonding material comprises a eutectic alloy.

4. The light emitting diode package according to claim 3, wherein the package substrate has a package electrode formed on an upper surface thereof, and the chip electrode and the package electrode are eutectic bonded.

5. The light emitting diode package according to claim 4, wherein the chip electrode comprises a material selected from the group consisting of Au-Sn, Au-Ni, Au-Ge, Au-Si, Au, Sn and Ni.

6. The light emitting diode package according to claim 4, wherein the package electrode comprises a material selected from the group consisting of Au-Sn, Au-Ni, Au-Ge, Au-Si, Au, Sn and Ni.

7. The light emitting diode package according to claim 4, wherein the chip electrode comprises an Au-Sn layer and the package electrode comprises an Au layer.

8. The light emitting diode package according to claim 4, wherein the chip electrode comprises an Au layer and the package electrode comprises an Au-Sn layer.

9. The light emitting diode package according to claim 1, wherein the bonding material comprises a cream solder.

10. The light emitting diode package according to claim 1, wherein the package substrate comprises one selected from the group consisting of a metal, ceramics, FR4, polyimide, Si and BT resin.

11. The light emitting diode package according to claim 1, further comprising a plating layer formed between the package substrate and the package electrode.

12. The light emitting diode package according to claim 11, wherein the plating layer comprises one selected from the group consisting of Au, Ni, Pt, Al and Ag.

13. The light emitting diode package according to claim 1, wherein the LED chip comprises a horizontal-structure LED chip having an insulation substrate.

14. The light emitting diode package according to claim 13, wherein the insulation substrate is bonded to the bonding surface of the package substrate, and the bonding material comprises an epoxy resin.

15. The light emitting diode package according to claim 14, wherein the epoxy resin comprises an Ag epoxy resin.

16. The light emitting diode package according to claim 1, wherein the recess is formed in a net shape.

17. The light emitting diode package according to claim 1, wherein the bonding material completely covers the recess.

18. The light emitting diode package according to claim 1, wherein the recess has a sectional shape selected from the group consisting of a rectangle, a triangle and a semicircle.
